(19) United States
(12) Patent Application Publication
(10) Pub. No.: US 2015/0372067 A1
(43) Pub. Date: Dec. 24, 2015

(54) ORGANIC LIGHT-EMITTING DISPLAY DEVICE AND METHOD OF MANUFACTURING THE SAME

(71) Applicant: SAMSUNG DISPLAY CO., LTD., Yongin-City (KR)

(72) Inventor: Jang-Sub KIM, Yongin-City (KR)

(21) Appl. No.: 14/566,866

(22) Filed: Dec. 11, 2014

(30) Foreign Application Priority Data
Jun. 20, 2014 (KR) 10-2014-0075892

(51) Int. Cl. H01L 27/32; H01L 51/00; H01L 51/56

(52) U.S. Cl. CPC H01L 27/3246; H01L 27/3223; H01L 51/56; H01L 51/0004; H01L 27/3258; H01L 2227/323; H01L 51/5012

(57) ABSTRACT

An organic light-emitting display device includes a substrate having an emission area and a dummy area that surrounds the emission area, a plurality of sub-pixels disposed on the emission area of the substrate, and a plurality of dummy pixels disposed on the dummy area of the substrate, each dummy pixel including a plurality of fine patterns.

### CROSS-REFERENCE TO RELATED APPLICATION

Korean Patent Application No. 10-2014-0075892, filed on Jun. 20, 2014, in the Korean Intellectual Property Office, and entitled: “Organic Light-Emitting Display Device and Method of Manufacturing the Same,” is incorporated by reference herein in its entirety.

### BACKGROUND

1. Field

One or more embodiments relate to an organic light-emitting display device and a method of manufacturing the organic light-emitting display device. More particularly, one or more embodiments relate to an organic light-emitting display device and a method of manufacturing the organic light-emitting display device, in which film formation that is performed using a solution process is easily controlled.

2. Description of the Related Art

Organic light-emitting display devices have a wider viewing angle, better contrast characteristics, and a faster response speed than other display devices, and thus have drawn attention as a next-generation display device. In general, organic light-emitting display devices operate so that thin film transistors control organic light emitting diodes formed on a substrate to emit light. Such organic light-emitting display devices may be used as display units of small products, e.g., mobile phones, and may also be used as display units of large products, e.g., televisions.

In general, organic light-emitting display devices have a pixel definition layer that covers an edge of a pixel electrode and exposes a center portion of the pixel electrode. After the pixel definition layer is formed, an intermediate layer including an emission layer is formed on the pixel electrode, e.g., by ink-jet printing, nozzle printing, or the like.

### SUMMARY

According to one or more embodiments, an organic light-emitting display device includes a substrate having an emission area and a dummy area that surrounds the emission area, a plurality of sub-pixels disposed on the emission area of the substrate, and a plurality of dummy pixels disposed on the dummy area of the substrate, each dummy pixel including a plurality of fine patterns.

The organic light-emitting display device may further include an insulation layer disposed on the substrate, and a pixel definition layer which is disposed on the insulation layer and comprises first apertures for defining the plurality of sub-pixels and second apertures for defining the plurality of dummy pixels. The fine patterns may be disposed within the second apertures of the pixel definition layer.

The organic light-emitting display device may further include a plurality of pixel electrodes disposed on the emission area of the substrate. The first apertures may cover edges of the plurality of pixel electrodes while exposing the center portion thereof and the second apertures may expose at least a portion of the insulation layer.

The fine patterns may be disposed on the at least portion of the insulation layer that is exposed via the second apertures of the pixel definition layer.

The fine patterns may include the same material as that used to form the pixel definition layer.

The fine patterns may include the same material as that used to form the plurality of pixel electrodes.

Each of the fine patterns may be formed in a lattice shape.

Each of the fine patterns may be formed in a symmetrical shape.

According to one or more embodiments of the present invention, a method of manufacturing an organic light-emitting display device includes preparing for a substrate comprising an emission area and a dummy area that surrounds the emission area; forming a plurality of pixel electrodes on the emission area of the substrate; forming a pixel definition layer that comprises first apertures for defining a plurality of sub-pixels on the emission area of the substrate and second apertures for defining a plurality of dummy pixels on the dummy area of the substrate; and forming fine patterns within the second apertures.

The method may further include forming an insulation layer on the substrate, between the preparing for the substrate and the forming of the plurality of pixel electrodes. In the forming of the pixel definition layer, the first apertures may expose respective centers of the plurality of pixel electrodes and the second apertures may expose at least a portion of the insulation layer.

In the forming of the fine patterns, the fine patterns may be disposed on the at least portion of the insulation layer that is exposed via the second apertures of the pixel definition layer.

In the forming of the fine patterns, the fine patterns may be formed simultaneously with the pixel definition layer.

In the forming of the fine patterns, the fine patterns may be formed simultaneously with the plurality of pixel electrodes.

In the forming of the fine patterns, the fine patterns may each be formed to have a lattice shape.

In the forming of the fine patterns, the fine patterns may each be formed to have a symmetrical shape.

The method may further include ejecting ink for intermediate layer formation onto the second apertures; and forming an intermediate layer by ejecting the ink for intermediate layer formation onto the first apertures.

The forming of the intermediate layer may be forming an intermediate layer according to a solution process.

### BRIEF DESCRIPTION OF THE DRAWINGS

Features will become apparent to those of ordinary skill in the art by describing in detail exemplary embodiments with reference to the attached drawings, in which:

FIG. 1 illustrates a schematic partial plan view of an organic light-emitting display device according to an embodiment;

FIG. 2 illustrates a magnified plan view of portion II in FIG. 1;

FIG. 3 illustrates a cross-sectional view along line III-III of FIG. 2;

FIG. 4 illustrates a schematic plan view of a method of manufacturing an organic light-emitting display device according to an embodiment; and

FIG. 5 illustrates a cross-sectional view of FIG. 4.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of” when preceding a list of elements, modify the entire list of elements and do not modify the individual elements of the list.

As embodiments allow for various changes, particular embodiments will be illustrated in the drawings and described in detail in the written description. Hereinafter, effects and features of embodiments and a method for accomplishing them will be described more fully with reference to the accompanying drawings, in which exemplary embodiments are shown. The embodiments, however, may be embodied in many different forms and should not be construed as limited to the exemplary embodiments set forth herein. Those components that are the same or are in correspondence are rendered the same reference numeral regardless of the figure number, and redundant explanations are omitted.

It will be understood that although the terms “first”, “second”, etc. may be used herein to describe various components, these components should not be limited by these terms. These components are only used to distinguish one component from another. As used herein, the singular forms “a”, “an”, and “the” are intended to include the plural forms as well, unless the context clearly indicates otherwise.

It will be further understood that the terms “comprises” and/or “comprising” used herein specify the presence of stated features or components, but do not preclude the presence or addition of one or more other features or components. It will be understood that when a layer, region, or component is referred to as being “formed on” another layer, region, or component, it can be directly or indirectly formed on the other layer, region, or component. That is, for example, intervening layers, regions, or components may be present.

Sizes of elements in the drawings may be exaggerated for convenience of explanation. In other words, since sizes and thicknesses of components in the drawings are illustrated for convenience of explanation, the following embodiments are not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When a certain embodiment may be implemented differently, a specific process order may be performed differently from the described order. For example, two consecutively described processes may be performed substantially at the same time or performed in an order opposite to the described order.

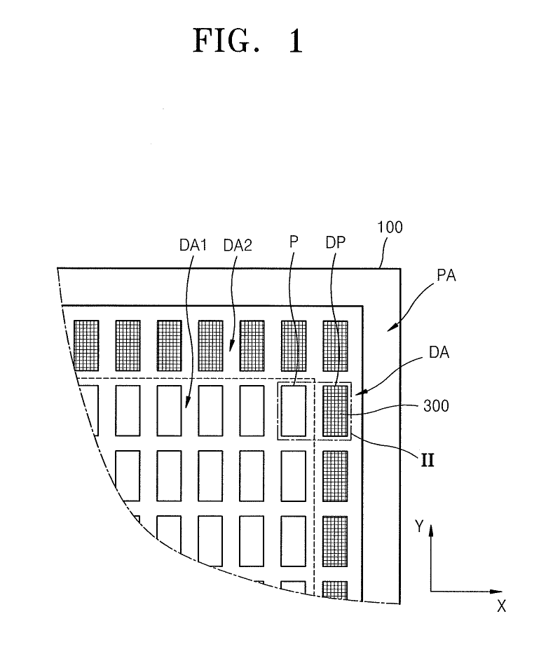

FIG. 1 is a schematic partial plan view of an organic light-emitting display device according to an embodiment.

Referring to FIG. 1, the organic light-emitting display apparatus may include a substrate 100, a plurality of sub-pixels P disposed on the substrate 100, a plurality of dummy pixels DP disposed on the substrate 100, and fine patterns 300 disposed within the dummy pixels DP.

The substrate 100 may be formed of any suitable material, e.g., glass, metal, or plastic such as polyethylene terephthalate (PET), polyethylene naphthalate (PEN), or polyimide. The substrate 100 may have a display area DA in which the sub-pixels P and the dummy pixels DP are disposed, and a peripheral area PA that surrounds the display area DA.

The display area DA of the substrate 100 may include an emission area DA1 and a dummy area DA2 that surrounds the emission area DA1. As illustrated in FIG. 1, the sub-pixels P may be disposed on the emission area DA1, and the dummy pixels DP may be disposed on the dummy area DA2. The sub-pixels P disposed on the emission area DA1 may be aligned along axes X and Y, and the dummy pixels DP disposed on the dummy area DA2 may be aligned side by side with the sub-pixels P disposed on the emission area DA1. For example, as illustrated in FIG. 1, the sub-pixels P may be disposed in the emission area DA1 in a matrix pattern, and the dummy pixels DP may be disposed in the dummy area DA2 to surround the sub-pixels P in the emission area DA, e.g., the dummy pixels DP may be aligned with corresponding adjacent sub-pixels P.

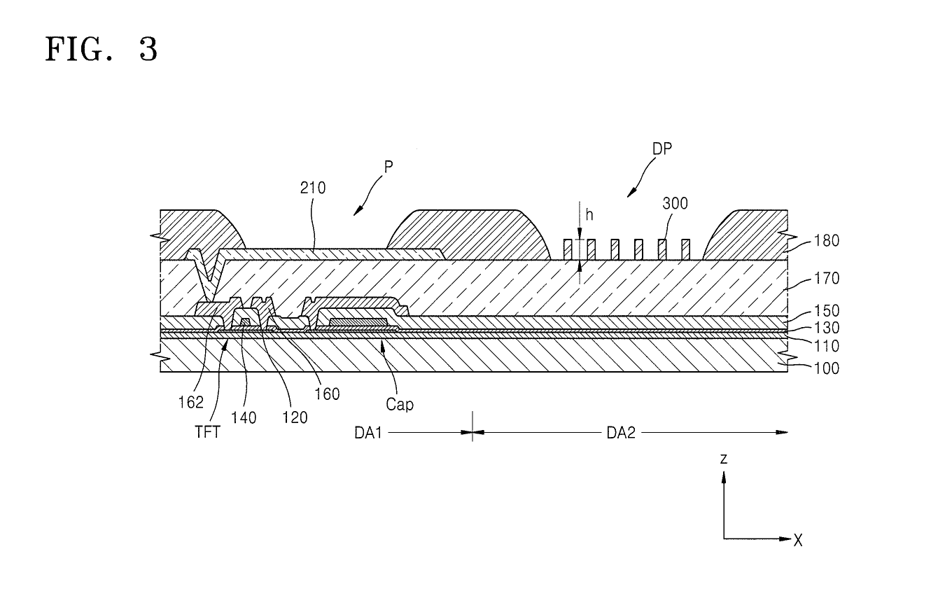

For example, as illustrated in FIG. 1, the dummy pixels DP may have the same size and shape as the sub-pixels P. In detail, as illustrated in FIG. 3, the dummy pixels DP may be spaces of the same size and shape as the sub-pixels P, but without electrodes. That is, as illustrated in FIG. 3, instead of the pixel electrodes 210, the dummy pixels DP include the fine patterns 300 on an insulation layer 170.

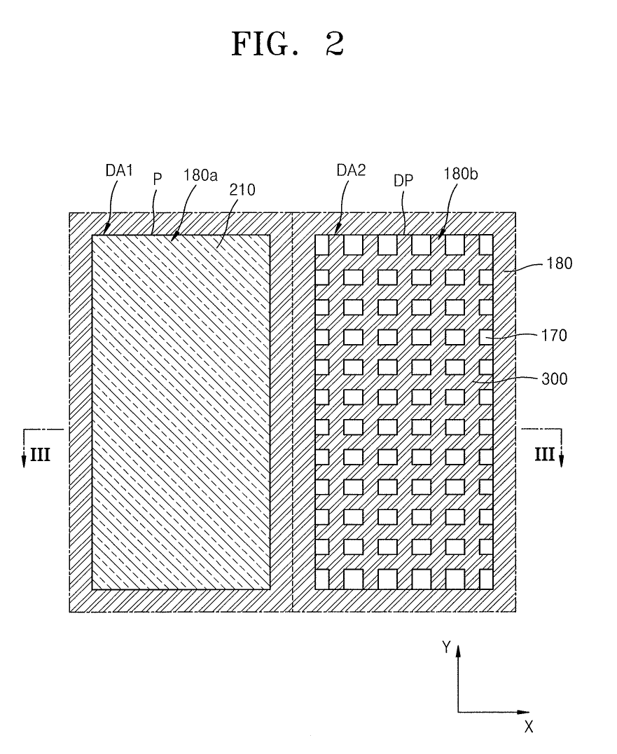

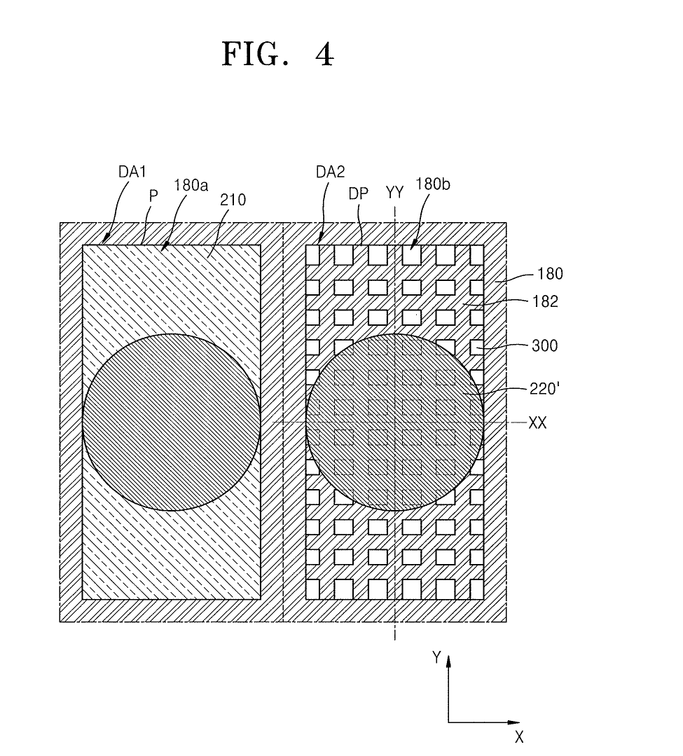

The fine patterns 300 may be disposed within the dummy pixels DP. Arranging the fine patterns 300 within the dummy pixels DP may denote arranging the fine patterns 300 within apertures defined as pixel regions by a pixel definition layer 180 (see FIG. 2). The fine patterns 300 may be lattice patterns, as illustrated in FIG. 1, but embodiments are not limited thereto. The fine patterns 300 may be disposed as symmetrical patterns within the apertures defined as pixel regions by the pixel definition layer 180. When the fine patterns 300 are formed in a lattice shape or a symmetrical shape within the dummy pixels DP as described above, ink 220′ (see FIG. 4) for an intermediate layer formation may be ejected onto the dummy pixels DP on which the fine patterns 300 are disposed, and thus the dropping position and dropping accuracy of the ejected ink 220′ may be substantially more easily measured.

FIG. 2 is a schematic magnified plan view of portion II of the organic light-emitting display device of FIG. 1. FIG. 3 is a cross-sectional view along line III-III of FIG. 2. It is noted that FIGS. 2-3 illustrate a sub-pixel P and a dummy pixel DP adjacent to each other along the x-axis.

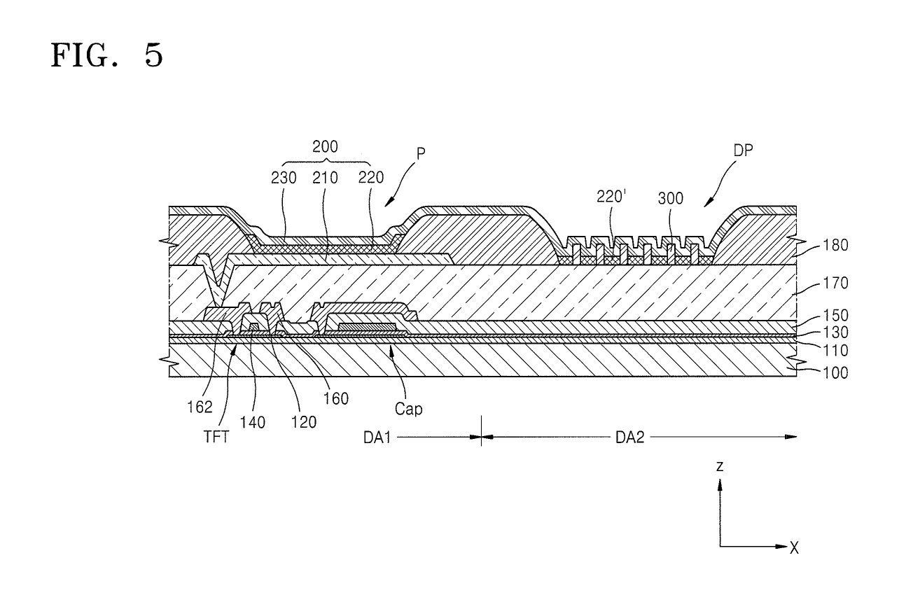

Referring to FIGS. 1-3, a plurality of thin film transistors TFT may be disposed on the display area DA of the substrate 100, and a plurality of organic light-emitting diodes (OLEDs) 200 (see FIG. 5) that are electrically connected to the thin film transistors TFT may also be disposed on the display area DA. Electrically connecting the OLEDs 200 to the thin film transistors TFT may be understood as electrically connecting a plurality of the pixel electrodes 210 to the thin film transistors TFT. As illustrated in FIG. 3, the thin film transistors TFT may be disposed on the emission area DA1, and no thin film transistors TFT may be disposed on the dummy area DA2. However, although not illustrated in FIG. 3, the thin film transistors TFT or wires may also be disposed on the dummy area DA2.

As illustrated in FIG. 3, each of the thin film transistors TFT may include a semiconductor layer 120, e.g., including amorphous silicon, crystalline silicon, or an organic semiconductor material, a gate electrode 140, a source electrode 160, and a drain electrode 162. To planarize the surface of the substrate 100 or prevent impurities or the like from permeating the semiconductor layer 120, a buffer layer 110 formed of, e.g., silicon oxide, silicon nitride, or the like may be disposed on the substrate 100, and the semiconductor layer 120 may be located on the buffer layer 110.

The gate electrode 140 is disposed on the semiconductor layer 120, and the source electrode 160 and the drain electrode 162 electrically communicate with each other in response to a signal applied to the gate electrode 140. For example, the gate electrode 140 may be formed of at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) in a single- or multi-layered structure, in consideration of adhesion to an adjacent layer, surface smoothness of a layer stacked on the gate electrode 140, and processability. To secure insulation between the semiconductor layer 120 and the gate electrode 140, a gate insulation layer 130, e.g., formed of silicon oxide and/or silicon nitride, may be interposed between the semiconductor layer 120 and the gate electrode 140.

An interlayer insulation layer 150 may be disposed on the gate electrode 140. The interlayer insulation layer 150 may be interposed between the gate electrode 140 and the source electrode 160 and between the gate electrode 140 and the drain electrode 162 to thereby insulate the gate electrode 140 from the source electrode 160 and the drain electrode 162. The interlayer insulation layer 150 may be formed of, e.g., silicon oxide, silicon nitride, or the like in a single- or multi-layered structure.

The source electrode 160 and the drain electrode 162 are disposed on the interlayer insulation layer 150. The source electrode 160 and the drain electrode 162 may be electrically connected to the semiconductor layer 120 via contact holes formed in the interlayer insulation layer 150 and the gate insulation layer 130. For example, the source electrode 160 and the drain electrode 162 may each be formed of at least one of aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and copper (Cu) in a single- or multi-layered structure, in consideration of conductivity or the like.

The insulation layer 170 may be disposed on the thin film transistors TFT to cover the thin film transistors TFT. In this case, the insulation layer 170 may be a planarization layer or a protective layer. For example, when the OLEDs 200 are disposed on the thin film transistors TFT, as illustrated in FIG. 5, the insulation layer 170 may be disposed as a planarization layer for planarizing upper surfaces of the thin film transistors TFT. The insulation layer 170 may be formed of, e.g., an acryl-based organic material, benzocyclobutene (BCB), or the like. Although the insulation layer 170 is a single layer in FIG. 3, various modifications may be made to the insulation layer 170. For example, the insulation layer 170 may be a stack of multiple layers.

Referring to FIG. 5, the OLEDs 200 are disposed on a portion of the insulation layer 170 that belongs to the emission area DA1. Each of the OLEDs 200 may include a pixel electrode 210, an opposite electrode 230 facing the pixel electrode 210, and an intermediate layer 220 interposed between the pixel electrode 210 and the opposite electrode 230 and including an emission layer.

An aperture that exposes at least one of the source electrode 160 and the drain electrode 162 of each thin film transistor TFT exists in the insulation layer 170, and each of the pixel electrodes 210 electrically connected to the thin film transistors TFT contacts at least one of the source electrode 160 and the drain electrode 162 via the aperture and is disposed on the insulation layer 170. The pixel electrodes 210 may be formed as transparent (or semi-transparent) electrodes or reflective electrodes. When the pixel electrodes 210 are formed as transparent (or semi-transparent) electrodes, the pixel electrodes 210 may be formed of, e.g., indium tin oxide (ITO), indium zinc oxide (IZO), zinc oxide (ZnO), indium oxide (In₂O₃), indium gallium oxide (IGO), or aluminum zinc oxide (AZO). When the pixel electrodes 210 are formed as reflective electrodes, the pixel electrodes 210 may include a reflective layer formed of, e.g., silver (Ag), magnesium (Mg), aluminum (Al), platinum (Pt), palladium (Pd), gold (Au), nickel (Ni), neodymium (Nd), iridium (Ir), chromium (Cr), or a combination thereof, and a layer formed of, e.g., ITO, IZO, ZnO, In₂O₃, IGO, or AZO. Of course, embodiments are not limited thereto, and the pixel electrodes 210 may be formed of any suitable material and may suitable structure, e.g., a single- or multi-layered structure.

The pixel definition layer 180 may be disposed on the insulation layer 170. The pixel definition layer 180 defines pixel regions. To achieve this, the pixel definition layer 180 may include first apertures 180a corresponding to the sub-pixels P disposed in the emission area DA1, e.g., the first apertures 180a may be openings through the pixel definition layer 180. For example, as illustrated in FIGS. 2-3, the pixel definition layer 180 covers, e.g., only, edges of the pixel electrodes 210, such that the first apertures 180a in the pixel definition layer 180 expose at least center portions of the pixel electrodes 210. As illustrated in FIG. 5, the pixel definition layer 180 prevents an arc from occurring on the edges of the pixel electrodes 210 by increasing distances between the edges of the pixel electrodes 210 and the opposite electrode 230 disposed on the pixel electrodes 210. The pixel definition layer 180 may be formed of an organic material, e.g., polyimide.

The pixel definition layer 180 also defines the dummy pixels DP. To achieve this, the pixel definition layer 180 also includes second apertures 180b corresponding to the dummy pixels DP disposed in the dummy area DA2. For example, the second apertures 180b expose at least a portion of the insulation layer 170 in the dummy area DA2. For example, the second apertures 180b may be only in the dummy area DA2, such that portions of the insulation layer 170 are exposed only in the dummy area DA2. Accordingly, the first apertures 180a in the pixel definition layer 180, which define the sub-pixels P, expose centers of the pixel electrodes 210, and the second apertures 180b in the pixel definition layer 180, which define the dummy pixels DP, expose the insulation layer 170 in the dummy area DA2.

Referring to FIG. 3, the fine patterns 300 may be disposed, e.g., directly, on the portion of the insulation layer 170 that is exposed via the second apertures 180b corresponding to the dummy pixels DP. The fine patterns 300 may be disposed as lattice patterns, as illustrated in FIG. 2, or may be also disposed as symmetrical patterns. The fine patterns 300 may be formed to include the same material as that used to form the pixel definition layer 180, or to include the same material as that used to form the pixel electrodes 210.

When the fine patterns 300 are formed to include the same material as that used to form the pixel definition layer 180, a height “h” of each fine pattern 300 may be the same as that of the pixel definition layer 180 or be less than that of the pixel definition layer 180 due to the use of a halftone mask or the like. Each fine pattern 300 may be formed to have a height less than or equal to half the height of the pixel definition layer 180, in consideration of the ejection amount of the ink 220′ (see FIG. 5) and the like.

When the fine patterns 300 as described above are used, after the ink 220′ for the intermediate layer formation is dropped, e.g., ejected, onto the dummy pixels DP, an accurate location where the ink 220′ is dropped may be ascertained by the densely arranged fine patterns 300. Thus, the center position of the ink 220′ is prevented from being changed as time passes, and accurate spreadability and dropping accuracy of the ink 220′ may be easily measured.

The intermediate layer 220 of the OLED 200 may include a small molecular material or a polymer. When the intermediate layer 220 includes a low molecular material, the intermediate layer 220 may be formed by stacking an emission layer (EML) and at least one of a hole injection layer (HIL), a hole transport layer (HTL), an electron transport layer (ETL), and an electron injection layer (EIL). Examples of an organic material used to form the intermediate layer 220 may include copper phthalocyanine (CuPc), N,N′-Di(naphthalene-1-yl)-N,N′-diphenyl-benzidine (NPB), and tris-8-hydroxyquinoline aluminum (Alq3). These layers may be formed by vacuum deposition or the like.

When the intermediate layer 220 includes a polymer material, the intermediate layer 220 may generally include an HTL and an EML. In this case, the HTL may be formed of poly(ethylenedioxythiophene) (PEDOT), and the EML may be formed of a polymer material, e.g., a polyphenylenevinylene (PPV)-based material or a polyfluorene-based material. The HTL and the EML may be formed by inkjet printing or the like. The intermediate layer 220 is not limited to the layer described above, and may have any of various structures.

The opposite electrode 230 may face the pixel electrode 210 with the intermediate layer 220 interposed between the opposite electrode 230 and the pixel electrode 210. The opposite electrode 230 may be disposed on the entire surface of the substrate 100. In other words, the opposite electrode 230 is incorporated into the OLED 200 to correspond to the pixel electrode 210.

The opposite electrode 230 may be formed as a transparent (or semi-transparent) electrode or a reflective electrode. When the opposite electrode 230 is formed as a transparent (or semi-transparent) electrode, the opposite electrode 230 may have a layer formed of a metal having a small work function, e.g., Li, Ca, LiF/Ca, LiF/Al, Al, Ag, Mg, or a combination thereof, and a transparent (or semi-transparent) conductive layer formed of, e.g., ITO, IZO, ZnO, or In₂O₃. When the opposite electrode 230 is formed as a reflective electrode, the opposite electrode 230 may have a layer formed of, e.g., Li, Ca, LiF/Ca, LiF/Al, Al, Ag, Mg, or a combination thereof. The configuration of the opposite electrode 230 and the material used to form the opposite electrode 230 are not limited to those described above, and various modifications may be made to the opposite electrode 230.

The ink 220′ for the intermediate layer formation in the organic light-emitting display device according to embodiments has a low solid content, e.g., of about 0.5% to about 2%, as compared with a color filter ink having a solid content of, e.g., about 20% to about 25%. Therefore, the ink 220′ for the intermediate layer formation may be very sensitive to changes in the characteristics and drying environment of the substrate 100. Accordingly, it would have been difficult to analyze an accurate location of where the ink 220′ for the intermediate layer formation were ejected and dropped into the apertures of the pixel definition layer 180 without the fine patterns 300, due to shape non-uniformity, location movement, and the like caused during a drying process. In addition, when the ink 220′ for the intermediate layer formation is ejected in the organic light-emitting display device that is formed into a thickness of about 50 nm, accuracy is needed for a method of measuring the spreadability or the like of the ink 220′.

Therefore, in a method of manufacturing the organic light-emitting display device, the ink 220′ for the intermediate layer formation is initially dropped onto the dummy pixels DP, and then an accurate location where the ink 220′ is dropped may be ascertained by the densely arranged fine patterns 300. Thus, the center position of the ink 220′ is prevented from being changed as time passes, and accurate spreadability and dropping accuracy of the ink 220′ may be very easily measured.

Although only an organic light-emitting display device has been described above, embodiments are not limited to this. For example, a method of manufacturing the organic light-emitting display device is within the scope of the embodiments.

FIG. 4 is a plan view schematically illustrating a method of manufacturing an organic light-emitting display device according to an embodiment. FIG. 5 is a cross-sectional view schematically illustrating the method of manufacturing the organic light-emitting display device.

Referring to FIGS. 4 and 5, the substrate 100 having the emission area DA1 and the dummy area DA2 surrounding the emission area DA1 may be prepared, and then the pixel electrodes 210 may be formed on the emission area DA1 of the substrate 100. Before the pixel electrodes 210 are formed, devices, e.g., the thin film transistors TFTs and capacitors, may be formed on the substrate 100. Although the thin film transistors TFTs are disposed only on the emission area DA1 in FIG. 5, embodiments are not limited thereto, and the thin film transistors TFT may also be disposed on the dummy area DA2.

The insulation layer 170 may be disposed on the thin film transistors TFT to cover the thin film transistors TFT. In this case, the insulation layer 170 may be a planarization layer or a protective layer. For example, when the OLEDs 200 are disposed over the thin film transistors TFT, as illustrated in FIG. 5, the insulation layer 170 may be disposed as a planarization layer for planarizing the upper surfaces of the thin film transistors TFTs. The insulation layer 170 may be formed of, e.g., an acryl-based organic material, benzocyclobutene (BCB), or the like. Although the insulation layer 170 is a single layer in FIG. 5, various modifications may be made to the insulation layer 170. For example, the insulation layer 170 may be a stack of multiple layers.

The pixel electrodes 210 electrically connected to the thin film transistors TFT may be formed on the insulation layer 170. The pixel electrodes 210 may be electrically connected to the source electrodes 160 or the drain electrodes 162 of the thin film transistors TFT via the apertures of the insulation layer 170.

Thereafter, the pixel definition layer 180 may be formed. The pixel definition layer 180 may be formed to have the first apertures 180a, which define the sub-pixels P, on the emission area DA1 of the substrate 100, and the second apertures 180b, which define the dummy pixels DP, on the dummy area DA2 of the substrate 100. The first apertures 180a formed on the emission area DA1 may be formed to cover the respective edges of the pixel electrodes 210 and expose the respective center portions thereof. The second apertures 180b formed on the dummy area DA2 may expose at least a portion of the insulation layer 170.

Thereafter, the fine patterns 300 may be formed within the second apertures 180b which define the dummy pixels DP. As described above, the second apertures 180b may be formed to expose at least a portion of the insulation layer 170, and the fine patterns 300 may be formed on portions of the insulation layer 170 that are exposed via the second apertures 180b.

The fine patterns 300 may be formed simultaneously with the pixel definition layer 180, or simultaneously with the pixel electrodes 210. In other words, the fine patterns 300 may be patterned simultaneously when the pixel definition layer 180 is formed, or simultaneously when the pixel electrodes 210 are formed. Forming the fine patterns 300 simultaneously with the pixel definition layer 180 denotes forming the fine patterns 300 of the same material as that used to form the pixel definition layer 180. Forming the fine patterns 300 simultaneously with the pixel electrodes 210 denotes forming the fine patterns 300 of the same material as that used to form the pixel electrodes 210.

When the fine patterns 300 are formed to include the same material as that used to form the pixel definition layer 180, the height “h” of each fine pattern 300 may be the same as that of the pixel definition layer 180 or be less than that of the pixel definition layer 180 due to the use of a halftone mask or the like. Each fine pattern 300 may be formed to have a height less than or equal to half the height of the pixel definition layer 180, in consideration of the ejection amount of the ink 220′ and the like.

Referring to FIG. 4, the fine patterns 300 in each dummy pixel DP may be formed in a lattice shape or in a symmetrical shape, e.g., the lattice-shaped fine patterns 300 may define a plurality of island-shaped openings spaced apart from each other in the x-axis and y-axis that expose portions of the insulating layer 170 through the fine patterns 300. Thereafter, the intermediate layer 220 may be formed. In this case, the formation of the intermediate layer 220 may include forming an intermediate layer according to a solution process. To form the intermediate layer 220, the ink 220′ for the intermediate layer formation may be ejected onto the dummy pixels DP, on which the fine patterns 300 are formed, and the sub-pixels P. In other words, the ink 220′ for the intermediate layer formation may be ejected onto, e.g., through, the first apertures 180a corresponding to the sub-pixels P and the second apertures 180b corresponding to the dummy pixels DP.

In this case, the ink 220′ for the intermediate layer formation may be ejected in the order from the dummy pixels DP disposed around the emission area DA1 to the sub-pixels P disposed on the emission area DA1. In other words, the ink 220′ may be ejected first to the dummy pixels DP, and only subsequently ejected to the sub-pixels P disposed on the emission area DA1.

In detail, after the ink 220′ for the intermediate layer formation is ejected onto the dummy pixels DP on which the fine patterns 300 are formed, the ink 220′ may spread on the fine patterns 300 and the portions of the insulating layer 170 exposed through the fine patterns 300 (FIGS. 4-5). For example, as the fine patterns 300 are densely arranged, e.g., as a calibrating grid, the location and spread of the ink 220′ in the fine patterns 300 of the dummy pixels DP may be accurately ascertained and measured. For example, after the ink 220′ for the intermediate layer formation is ejected onto the dummy pixels DP, the ink 220′ is observed relative to the fine patterns 300 to determine spreadability and accuracy of deposition. Thus, the center position of the ink 220′ is prevented from being changed as time passes, and accurate spreadability and dropping accuracy of the ink 220′ may be easily measured. As such, as illustrated in FIG. 4, the ink 220′ for the intermediate layer formation may be ejected onto the respective centers of the sub-pixels P, in accordance with the observation and measurement of the ink 220′ in the dummy pixels DP. Thus, accurate spreadability and dropping accuracy of the ink 220′ may be easily ascertained by observing the fine patterns 300 with lattice shapes formed within the dummy pixels DP to determine whether the ink 220′ for the intermediate layer formation is dropped onto the centers of the dummy pixels DP, i.e., the centers at which an axis XX and an axis YY intersect, before the ink 220′ for intermediate layer formation is ejected onto the sub-pixels P.

As described above, according to an organic light-emitting display device and a method of manufacturing the same, the dropping accuracy of ink used to form a layer is easily measured. In contrast, in a conventional organic light-emitting display device and a method of manufacturing the same, spreadability and dropping accuracy of ink may not be easily measured in a process of ejecting ink in order to form an intermediate layer.

Example embodiments have been disclosed herein, and although specific terms are employed, they are used and are to be interpreted in a generic and descriptive sense only and not for purpose of limitation. For example, these general and specific terms may be implemented by using a system, a method, a computer program, or a combination of the system, the method, and the computer program. Accordingly, it will be understood by those of skill in the art that various changes in form and details may be made without departing from the spirit and scope of the present invention as set forth in the following claims.

What is claimed is:

1. An organic light-emitting display device, comprising:
a substrate having an emission area and a dummy area that surrounds the emission area;
a plurality of sub-pixels on the emission area of the substrate; and
a plurality of dummy pixels on the dummy area of the substrate, each dummy pixel including a plurality of fine patterns.

2. The organic light-emitting display device as claimed in claim 1, further comprising:
an insulation layer on the substrate; and
a pixel definition layer on the insulation layer, the pixel definition layer including first apertures defining the plurality of sub-pixels and second apertures defining the plurality of dummy pixels,
wherein the fine patterns are within the second apertures of the pixel definition layer.

3. The organic light-emitting display device as claimed in claim 2, further comprising a plurality of pixel electrodes on the emission area of the substrate,
wherein the first apertures cover edges of the plurality of pixel electrodes while exposing center portions thereof, and the second apertures expose at least a portion of the insulation layer in the dummy area.

4. The organic light-emitting display device as claimed in claim 3, wherein the fine patterns are on the at least portion of the insulation layer that is exposed via the second apertures of the pixel definition layer.

5. The organic light-emitting display device as claimed in claim 4, wherein the fine patterns include a same material as that of the pixel definition layer.

6. The organic light-emitting display device as claimed in claim 4, wherein the fine patterns include a same material as that of the pixel electrodes.

7. The organic light-emitting display device as claimed in claim 1, wherein the fine patterns are arranged in a lattice shape.

8. The organic light-emitting display device as claimed in claim 1, wherein the fine patterns are arranged in a symmetrical shape.

9. A method of manufacturing an organic light-emitting display device, the method comprising:
preparing a substrate having an emission area and a dummy area that surrounds the emission area;
forming a plurality of pixel electrodes on the emission area of the substrate;
forming a pixel definition layer on the substrate, the pixel definition layer including first apertures defining a plurality of sub-pixels on the emission area of the substrate, and second apertures defining a plurality of dummy pixels on the dummy area of the substrate; and
forming fine patterns within the second apertures.

10. The method as claimed in claim 9, further comprising forming an insulation layer on the substrate, the insulation layer being formed after preparing the substrate and before forming the plurality of pixel electrodes,
wherein forming the pixel definition layer includes forming the first apertures to expose respective centers of the plurality of pixel electrodes, and forming the second apertures to expose at least a portion of the insulation layer in the dummy area.

11. The method as claimed in claim 10, wherein forming the fine patterns includes forming the fine patterns on at least a portion of the insulation layer that is exposed via the second apertures of the pixel definition layer.

12. The method as claimed in claim 11, wherein forming the fine patterns includes forming the fine patterns simultaneously with the pixel definition layer.

13. The method as claimed in claim 11, wherein forming the fine patterns includes forming the fine patterns simultaneously with the plurality of pixel electrodes.

14. The method as claimed in claim 9, wherein forming the fine patterns includes forming the fine patterns in a lattice shape.

15. The method as claimed in claim 9, wherein forming the fine patterns includes forming the fine patterns in a symmetrical shape.

16. The method as claimed in claim 9, further comprising:
forming an insulation layer on the substrate;
ejecting ink onto the insulation layer and the fine pattern through the second apertures; and
forming an intermediate layer by ejecting the ink through the first apertures onto the first electrodes.

17. The method as claimed in claim 16, wherein forming the intermediate layer includes forming the intermediate layer according to a solution process.
